(19) United States
(12) Patent Application Publication
(10) Pub. No.: US 2009/0166874 A1
(43) Pub. Date: Jul. 2, 2009

(54) Semiconductor Device and Method of Fabricating the Same

(76) Inventor: Jang Hyeon Seok, Icheon-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/271,119

(22) Filed: Nov. 14, 2008

(30) Foreign Application Priority Data
Dec. 26, 2007 (KR) 10-2007-0137274

(51) Int. Cl. H01L 23/52; H01L 21/4763

(52) U.S. Cl. 257/762; 438/648; 257/E23.141; 257/E21.495

(57) ABSTRACT

A semiconductor device and manufacturing method thereof are provided. The semiconductor device can include an interlayer dielectric layer on a substrate, a metal layer on the interlayer dielectric layer, and an impure anti-reflection film on the metal layer. The impure anti-reflection film can be formed through an in situ process.

### CROSS-REFERENCE TO RELATED APPLICATION

The present application claims the benefit under 35 U.S.C. § 119 of Korean Patent Application No. 10-2007-0137274, filed Dec. 26, 2007, which is hereby incorporated by reference in its entirety.

### BACKGROUND

In the fabrication of semiconductor devices, an anti-reflection film is often formed on a metal line.

In a related art method for fabricating a semiconductor device, a sintering process is typically formed by means of annealing after forming a metal wiring in order to improve the performance of the device. However, referring to FIG. 1, according to the related art process, when the sintering process is performed, thermal stress causes a metal void (V) to occur due to a difference between the thermal expansion coefficients of a metal line and an interlayer dielectric layer. The void can also be caused by interface reaction between the metal line and an anti-reflection film. This void can deteriorate reliability of the device.

### BRIEF SUMMARY

Embodiments of the present invention provide a semiconductor device capable of inhibiting formation of a metal void caused by thermal stress when performing a sintering process, and a method of fabricating the same.

In an embodiment, a semiconductor device can comprise: an interlayer dielectric layer on a substrate; a metal layer on the interlayer dielectric layer; and an impure anti-reflection film on the metal layer.

In another embodiment, a method of fabricating a semiconductor device can comprise: forming an interlayer dielectric layer on a substrate; forming a metal layer on the interlayer dielectric layer; forming an impure anti-reflection film on the metal layer; and forming a metal line by selectively etching the metal layer and the impure anti-reflection film. In a further embodiment, a sintering process can be performed on the substrate including the metal line.

According to embodiments of the present invention, when depositing the metal layer, an in situ process can be applied to form the impure anti-reflection film, thereby making it possible to minimize changes in thermal stress according to the sintering process and effectively inhibit formation of a metal void.

Also, according to embodiments, stress migration properties can be improved, thereby improving margins of the metal process and reliability of products.

### BRIEF DESCRIPTION OF THE DRAWINGS

FIG. 1 is a photo showing a metal void generated in a metal line of a related art semiconductor device.

FIG. 2 is a cross-sectional view of a metal line of a semiconductor device according to an embodiment of the present invention.

FIG. 3 shows stress versus temperature on a metal line for a related art device and devices according to embodiments of the present invention.

FIG. 4 shows stress and stress variation on a metal line for a related art device and a semiconductor device according to an embodiment of the present invention.

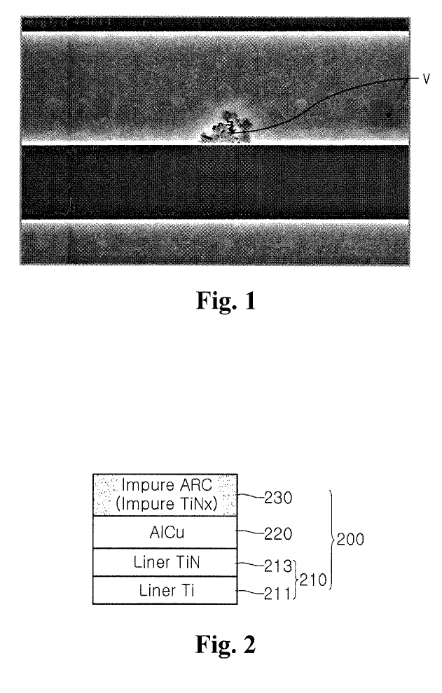

### DETAILED DESCRIPTION

Hereinafter, semiconductor devices and manufacturing methods thereof according to embodiments of the present invention will be described in detail with reference to the accompanying drawings.

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

Though the present invention is described herein with reference to an image sensor, embodiments are not limited thereto. A skilled artisan will recognize that embodiments can be applied to any semiconductor device where an anti-reflection film is present and a sintering process is performed.

FIG. 2 is a cross-sectional view of a metal line of a semiconductor device according to an embodiment of the present invention.

Referring to FIG. 2, a semiconductor device can include an interlayer dielectric layer (not shown) formed on a substrate (not shown). A metal layer 220 can be formed on the interlayer dielectric layer, and an impure anti-reflection film (Impure ARC) 230 can be formed on the metal layer 220. Though the metal layer 220 is shown as AlCu by way of example, embodiments of the present invention are not limited thereto. The metal layer 220 can comprise any suitable material known in the art.

In an embodiment, the impure anti-reflection film (Impure ARC) 230 can be an impure TiNₓ film (where x is a positive integer or zero). In a further embodiment, the impure anti-reflection film 230 can include Ti and/or TiNₓ (where x is less than 1). In a further embodiment, the impure anti-reflection film 230 can be a Ti—TiN layer.

The impure anti-reflection film (Impure ARC) 230 can be formed to any suitable thickness. For example, the impure anti-reflection film 230 can have a thickness of from about 300 Å to about 375 Å.

In an embodiment, a metal line 200 can also include a liner layer 210 disposed under the metal layer 220. The liner layer 210 can include a first liner layer 211 and a second liner layer 213.

Though the first liner layer 211 and the second liner layer 213 are shown in FIG. 2 as Ti and TiN, respectively, embodiments of the present invention are not limited thereto. The first liner layer 211 and the second liner layer 213 can each comprise any suitable material known in the art.

in situin situin situMethods of fabricating a semiconductor device will now be described with reference to FIG. 2.

An interlayer dielectric layer (not shown) can be formed on a substrate (not shown). The interlayer dielectric layer can be, for example a pre-metal dielectric (PMD) or an inter-metal dielectric (IMD).

In an embodiment, a liner layer 210 can be formed on the interlayer dielectric layer. The liner layer 210 can include a first liner layer 211 and a second liner layer 213 formed on the first liner layer 211. Though FIG. 12 shows the first liner layer 211 as a Ti liner layer 211 and the second liner layer 213 as a TiN liner layer, embodiments are not limited thereto. The first liner layer 211 and the second liner layer 213 can each comprise any suitable material known in the art.

Next, a metal layer 220 can be formed on the liner layer 210. For example, the metal layer can be formed of AlCu, though embodiments of the present invention are not limited thereto. The metal layer 220 can be formed of any suitable material known in the art.

Next, an impure anti-reflection film (Impure ARC) 230 can be formed on the metal layer 220. In an embodiment, forming the impure anti-reflection film (Impure ARC) 230 can include forming a first anti-reflection film (not shown) and processing a second anti-reflection film (not shown) on the first anti-reflection film through an in situ process.

For example, the first anti-reflection can be formed of a Ti film, and the second anti-reflection film can be formed of a TiN film through the in situ process, but embodiments of the present invention are not limited thereto.

In an embodiment, after the first anti-reflection (Ti film is formed, the second anti-reflection TiN film can be processed through the in situ process to form an impure TiNₓ film (where x is a positive integer). Accordingly, the formation of TiAl₃ due to an interface reaction between the Ti film and the AlCu metal layer 220 can be minimized, thereby making it possible to inhibit formation of a metal void due to the sintering process.

In an embodiment, the first anti-reflection film can have a thickness of from about 20% to about 50% of a thickness of the second anti-reflection film.

The impure anti-reflection film (Impure ARC) 230 can be formed to any suitable thickness known in the art. For example, the impure anti-reflection film 230 can have a thickness of from about 300 Å to about 375 Å. Even as the thickness of the impure anti-reflection film (Impure ARC) 230 increases, the volume shrinkage of the metal line due to formation of TiAl₃ can be inhibited, thereby making it possible to improve surface morphology and overcome Rs drift issues. That is, Em/SM properties of the metal can be improved.

It should be noted that, in certain embodiments, a hydrogen (H) trap in the Ti film can be increased, thereby deteriorating dark properties, such that the Ti film can have a thickness of from about 50 Å to about 125 Å.

In an embodiment, the TiN film can have a thickness of about 250 Å. The TiN film can secure sufficient margins during subsequent photo/exposure processes.

Also, in an embodiment, during the formation of the impure anti-reflection film (Impure ARC) 230, power of from about 5 kW to about 10 kW can be consumed.

In an embodiment, the deposition rate of the first anti-reflection film can be higher than that of the second anti-reflection film. For example, in the case of Ti film, the formation of TiAl₃ can be minimized by increasing the deposition rate. In the case of TiN film, a dense film can be formed by decreasing the deposition rate. This can inhibit the attack on Al during subsequent photo processes.

Also, the impure anti-reflection film (Impure ARC) 230 can be formed by a process at a temperature of about 50° C. or less. For example, the Ti film and the TiN film can each be deposited at a temperature of less than or equal to about 50° C.

Copper segregation (forming E phase), which can be caused by a long holding time within a chamber (at a temperature of about 200° C.), can cause a short to occur in the metal line leading to a loss in yield. In order to overcome such a problem, the in situ process for forming the impure anti-reflection film 230 can use a low temperature process of about 50° C. or less.

In an embodiment, forming the first anti-reflection film can be performed under an argon (Ar) gas atmosphere, and forming the second anti-reflection film can be performed under an Ar gas atmosphere and under a nitrogen gas (N₂) atmosphere. In a further embodiment, the Ar gas atmosphere for the first anti-reflection film can be provided at a flow rate of from about 60 standard cubic centimeters per minute (sccm) to about 100 sccm, the Ar gas atmosphere for the second anti-reflection film can be provided at a flow rate of from about 40 sccm to about 60 sccm, the N₂ atmosphere for the second anti-reflection film can be provided at a flow rate of from about 80 sccm to about 120 sccm.

For example, the in situ process for forming the impure anti-reflection film (Impure ARC) 230 can use about 80 sccm of Ar for the first anti-reflection film and about 50 sccm of Ar and about 100 sccm of N₂ for the second anti-reflection film in order to form a dense impure TiNₓ film structure (where x is a positive integer). This can be provided to inhibit attack on Al during a subsequent photo process.

Next, a metal line 200 can be formed by selectively etching the metal layer 220 and the impure anti-reflection film 230.

Thereafter, a sintering process can be performed on the substrate including the metal line 200.

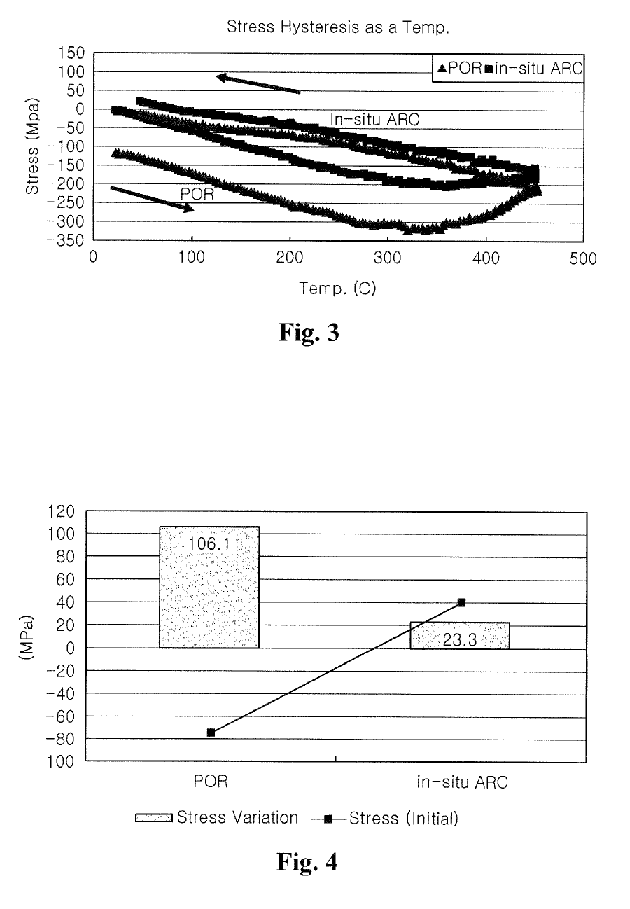

FIG. 3 shows stress versus temperature on a metal line, and FIG. 4 shows stress and stress variation for a related art device and a semiconductor device according to an embodiment of the present invention.

Referring to FIG. 3, the prior art (POR) device shows a rapid decrease in thermal stress as the temperature increases.

The semiconductor device according to an embodiment of the present invention, on the other hand, shows a much less rapid decline in stress as temperature increases. The embodiment includes formation of an impure anti-reflection film by applying an in situ process to strengthen the tensile stress properties compared to the prior art (POR). This leads to a smaller change in stress before and after the sintering process at a temperature of about 450° C. The formation of a metal void due to the sintering process can thereby be efficiently inhibited by having sufficient margins against the thermal stress as described above.

Referring to FIG. 4, the prior art (POR) device has a high stress variation of about 106 MPa, while the embodiment of the present invention shows about 23 MPa by forming an impure anti-reflection film by applying an in situ process.

In other words, with the semiconductor device according to the embodiment, the impure anti-reflection film can be formed by applying the in situ process when the metal layer is deposited, making it possible to minimize changes in thermal stress during to the sintering process and efficiently inhibit formation of a metal void.

According to embodiments of the present invention, the impure anti-reflection film can be formed by applying an in situ process when the metal layer is deposited so that the change in thermal stress according to the sintering process can be minimized, thereby inhibiting formation of a the metal void.

Also, the stress migration (SM) properties can be improved, making it possible to improve the margins of the metal process and the reliability of products.

The present invention should not be construed as limited to the embodiments set forth herein and may be changed in many different forms within the spirit and scope of the appended claims.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
an interlayer dielectric layer on a substrate;
a metal layer on the interlayer dielectric layer; and
an impure anti-reflection film on the metal layer.

2. The semiconductor device according to claim 1, wherein the impure anti-reflection film comprises a TiNₓ film, wherein x is a positive integer or zero.

3. The semiconductor device according to claim 2, wherein the metal layer comprises AlCu.

4. The semiconductor device according to claim 2, wherein the impure anti-reflection film has a thickness of from about 300 Å to about 375 Å.

5. The semiconductor device according to claim 1, wherein the impure anti-reflection film is formed by an in situ process.

6. The semiconductor device according to claim 1, wherein the impure anti-reflection film has a thickness of from about 300 Å to about 375 Å.

7. The semiconductor device according to claim 1, wherein the impure anti-reflection film comprises a Ti—TiN layer.

8. The semiconductor device according to claim 1, wherein the metal layer comprises AlCu.

9. A method of fabricating a semiconductor device, comprising:
forming an interlayer dielectric layer on a substrate;
forming a metal layer on the interlayer dielectric layer;
forming an impure anti-reflection film on the metal layer; and
forming a metal line by selectively etching the metal layer and the impure anti-reflection film.

10. The method according to claim 9, further comprising:
performing a sintering process on the substrate including the metal line.

11. The method according to claim 9, wherein forming the impure anti-reflection film comprises:
forming a first anti-reflection film; and
forming a second anti-reflection film on the first anti-reflection film through an in situ process.

12. The method according to claim 11, wherein the first anti-reflection film is a Ti film, and wherein the second anti-reflection film is a TiN film.

13. The method according to claim 11, wherein a thickness of the first anti-reflection film is from about 20% to about 50% of a thickness of the second anti-reflection film.

14. The method according to claim 11, wherein a deposition rate of the first anti-reflection film is higher than a deposition rate of the second anti-reflection film.

15. The method according to claim 11, wherein forming the first anti-reflection film comprises forming the first anti-reflection film under an argon (Ar) gas atmosphere, and wherein forming the second anti-reflection film comprises forming the second anti-reflection film under an Ar gas atmosphere and under a nitrogen (N₂) gas atmosphere.

16. The method according to claim 15, wherein the Ar gas for the first anti-reflection film is provided at a flow rate of from about 60 sccm to about 100 sccm, and wherein the Ar gas for the second anti-reflection film is provided at a flow rate of from about 40 sccm to about 60 sccm, and wherein the N₂ gas is provided at a flow rate of from about 80 sccm to about 120 sccm.

17. The method according to claim 9, wherein the impure anti-reflection film comprises a TiNₓ film, where x is a positive integer or zero.

18. The method according to claim 9, wherein forming the impure anti-reflection film comprises processing the impure anti-reflection film at a temperature of about 50° C. or less.
